(19) United States
(12) Patent Application Publication
(10) Pub. No.: US 2026/0321310 A1
(43) Pub. Date: Oct. 15, 2026

(54) MEMORY DEVICES WITH CONTROLLER CONFIGURED TO SELECT ONE OF VARIOUS REFERENCE SCHEMES AND METHODS FOR OPERATING THE SAME

(71) Applicant: Taiwan Semiconductor Manufacturing Company, Ltd., Hsinchu (TW)

(72) Inventors: Yen-Cheng Chiu, Hsinchu City (TW); Yi-Chun Shih, Hsinchu City (TW); Ku-Feng Lin, Hsinchu City (TW); Tung-Cheng Chang, Hsinchu City (TW); Sheng-Po Huang, Hsinchu City (TW); Yih Wang, Hsinchu City (TW)

(73) Assignee: Taiwan Semiconductor Manufacturing Company, Ltd., Hsinchu (TW)

(21) Appl. No.: 19/265,346

(22) Filed: Jul. 10, 2025

Related U.S. Application Data
(60) Provisional application No. 63/788,391, filed on Apr. 14, 2025.

(51) Int. Cl. G11C 13/00

(52) U.S. Cl. CPC G11C 13/004; G11C 13/0028; G11C 13/0069

(57) ABSTRACT

A semiconductor device includes a first memory array comprising a plurality of first nominal memory cells, a plurality of first reference memory cells, and a plurality of second reference memory cells; a second memory array comprising a plurality of second nominal memory cells, a plurality of third reference memory cells, and plurality of fourth reference memory cells; an input/output (I/O) circuit physically interposed between the first memory array and the second memory array along a first lateral direction; and a controller operatively coupled to the I/O circuit, the first memory array, and the second memory array. Based on a plurality of control signals, the controller is configured to select a reference signal from one of the third reference memory cells, the fourth reference memory cells, or the second nominal memory cells, thereby allowing the I/O circuit to sense a data signal from one of the first nominal memory cells.

### CROSS-REFERENCE TO RELATED APPLICATION

This application claims priority to and the benefit of U.S. Provisional Application No. 63/788,391, filed Apr. 14, 2025, which is incorporated herein by reference in its entirety for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory device, in accordance with some embodiments.

FIG. 2 illustrates an example circuit diagram of one memory cell of the memory device of FIG. 1, in accordance with some embodiments.

FIG. 3 illustrates an example schematic diagram of the memory device of FIG. 1, in accordance with some embodiments.

FIG. 4 illustrates another example schematic diagram of the memory device of FIG. 1, in accordance with some embodiments.

FIG. 5 illustrates an example circuit diagram of a memory controller of the memory device of FIG. 1, in accordance with some embodiments.

FIGS. 6 to 8 illustrate an example when a segmented reference scheme is applied, in accordance with some embodiments.

FIGS. 9 to 11 illustrate an example when a global reference scheme is applied, in accordance with some embodiments.

FIGS. 12 to 15 illustrate an example when a quasi-reference scheme is applied, in accordance with some embodiments.

FIGS. 16 to 18 illustrate an example when a local reference scheme is applied, in accordance with some embodiments.

FIG. 19 illustrates an example flowchart of a method for operating a memory device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus maybe otherwise oriented (rotated 90 degrees or at other orientations) and the spatially relative descriptors used herein may likewise be interpreted accordingly.

Some (e.g., non-volatile) memory devices, such as magnetic random-access memory (MRAM) devices, phase-change random-access memory (PCRAM) devices, and resistive random-access memory (RRAM) devices, store data bits by programming respective resistances of their memory cells. Typically, in a read operation, a data bit (or signal) is read from one of these memory cells and compared to a reference value, such as a reference voltage or a reference current. The comparison result is provided as an output data bit (or signal). In the modern memory devices with programmable resistances, different reference schemes or structures can be used to provide the above-mentioned reference values that are compared to the data bits received from the memory cells to provide output data bits.

For example, a memory device can include one or more (global) reference memory cell sets. In accordance with the scaling trend, the memory device may include multiple memory arrays, each of which includes at least one global reference memory cell set. Each of the global reference memory cell sets can be shared by 128 or more different word lines, where each word line is connected to many different memory cells in bit lines. Each of the reference memory cell sets is configured to provide reference values for all the memory cells connected to the 128 or more different word lines. However, one reference memory cell set cannot closely track or follow so many different memory cells due, at least in part, to column loading effects, such as bit line and source line resistance variations. Thus, in the memory devices with the global reference memory cell sets, a major concern is yield loss and/or higher read error rates.

For another example, a memory device can include one or more (local) reference memory cell sets. Each of the local reference memory cell sets is utilized per word line. The area of the reference memory cell sets occupy about 8% of the memory device area, such as in a memory device that has common source lines (CSL) of 4 columns and a multiplexer for 32 columns. Also, a large amount of reference trim code is included due to the large number of local reference memory cells. The reference trim code storage occupies about 3% of the memory device area. Thus, in the memory devices with the local reference memory cell sets, a major concern is area overhead.

The present disclosure provides various embodiments of a memory device with a plurality of reference schemes or structures that can be selectively or otherwise adaptively applied based on multiple process variations (e.g., bit line/source line variation, read disturbance, read margin, etc.). As such, the memory device, as disclosed herein, can balance the trade-off between yield loss, error rates, and device area.

For example, the memory device can selectively apply one of the plural reference schemes to one of the selected memory cells, while reading the selected memory cell. The memory device can include a first memory array, a second memory array, and a memory controller. Each of the memory arrays can include a plural number of (e.g., nominal) memory cells each configured to store a data bit (or a data signal), and a plural number of (e.g., reference) memory cells each configured to store a reference value (or a reference signal). According to some embodiments, some of the reference memory cells may be configured as one of a plural number of global reference memory cell sets (corresponding to a global reference scheme), some of the reference memory cells may be configured as one of a plural number of segmented reference memory cell sets (corresponding to a segmented reference scheme), some of the reference memory cells may be configured as one of a plural number of local reference memory cell sets (corresponding to a local reference scheme), and some of the nominal memory cells may be configured or enlisted as one of a plural number of quasi-reference memory cell sets (corresponding to a quasi-reference scheme).

The memory controller can be operatively coupled to the first memory array through a respective number of first (e.g., word line) drivers, and to the second memory array through a respective number of second (e.g., word line) drivers. Each of the first or second word line drivers is operatively coupled to a respective number of memory cells through a respective word line. With the word line driver being selected (e.g., activated), the corresponding word line is asserted. As such, the memory controller can in turn access the corresponding memory cells to retrieve the stored data bit or reference value. Further, in some embodiments, the memory controller can operatively select one of the reference schemes based on a plural number of control or enable signals (e.g., a REFG_EN signal, a QSI_EN signal, a LOC_EN signal). Based on a logic combination of those control signals (associated with a respective one of the reference schemes), the memory controller can activate one of the word line drivers then to activate a corresponding reference memory cell or a corresponding nominal memory cell, thereby providing its reference value to be compared with a read data bit.

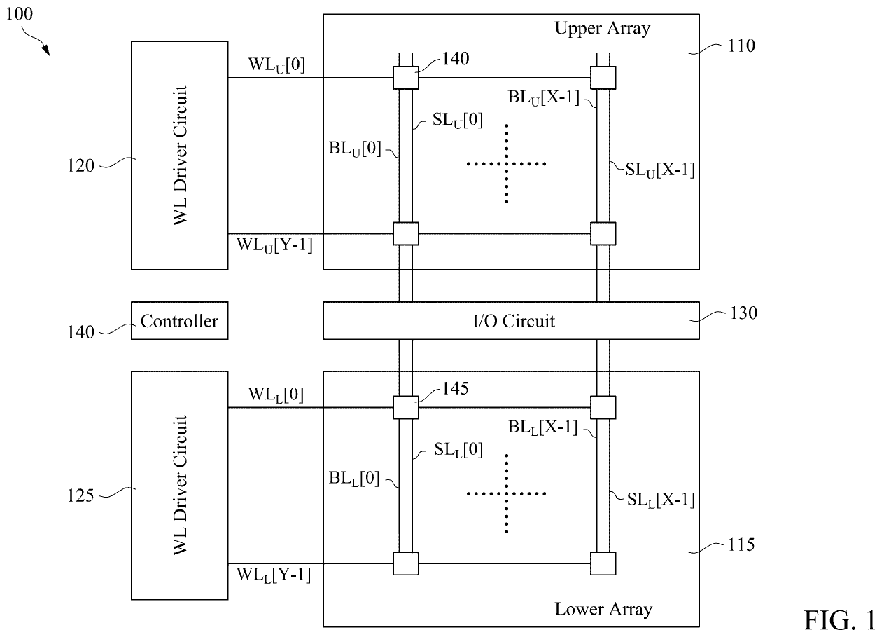

FIG. 1 illustrates an example block diagram of a memory circuit (or device) 100, in accordance with various embodiments of the present disclosure. As shown, the memory circuit 100 includes a number of memory arrays, 110, 115, etc., a number of word line (WL) driver circuits, 120, 125, etc., an input/output (I/O) circuit 130, and a memory controller 140. It should be appreciated that the block diagram of FIG. 1 has been simplified for illustrative purposes, and thus, the memory circuit 100 can include any of various other components, e.g., a sinker circuit, a source line (SL) driver, a pre-charge circuit, etc., while remaining within the scope of the present disclosure, in accordance with some embodiments of the present disclosure.

In some embodiments, the memory arrays 110 and 115 can operatively share the I/O circuit 130 and the memory controller 140. For example, the memory controller 140 can operate the memory array 110 through the WL driver circuit 120, and operate the memory array 115 through the WL driver circuit 125. In some embodiments, the I/O circuit 130 may be physically disposed between the memory arrays 110 and 115 along a first lateral direction (e.g., the Y-axis), with the WL driver circuit 120 and the WL driver circuit 125 physically disposed next to the memory array 110 and the memory array 115, respectively, along a second lateral direction (e.g., the X-axis). Further, the memory controller 140 can be physically disposed next to the I/O circuit 130 along the second lateral direction, and between the WL driver circuit 120 and the WL driver circuit 125 along the first lateral direction. According to this arrangement, the memory arrays 110 and 115 may sometimes be referred to as an upper memory array (or upper memory bank) and a lower memory array (or lower memory bank), respectively. However, it should be understood that the components of the memory circuit 100 can be arranged in any other way, while remaining within the scope of the preset disclosure.

Each of the memory arrays 110 and 115 can include a plurality of storage circuits or memory cells. For example, in FIG. 1, the upper memory array 110 includes a plurality of storage circuits or memory cells 140 and the lower memory array 115 includes a plurality of storage circuits or memory cells 145, which may be arranged in two-dimensional or three-dimensional arrays. In some embodiments, each of the memory cells 140 and 145 includes an RRAM cell configured to store a data bit corresponding to either a high resistance state (high resistance) or a low resistance state (low resistance). However, each of the memory cells 140 and 145 can include any of various other configuration of memory cells, while remaining within the scope of the present disclosure. For example, each of the memory cells 140 and 145 can include an MRAM cell, a spintronic memory cell, or an OTP memory cell.

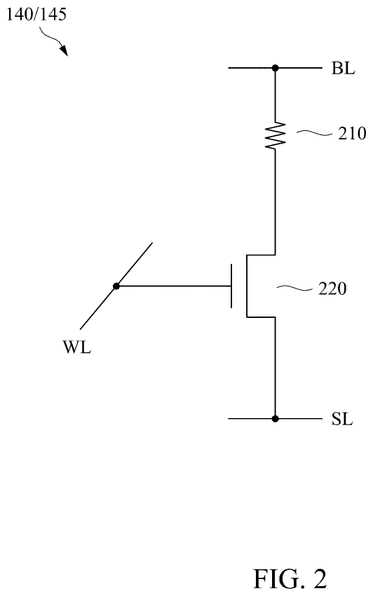

As will be shown below in FIG. 2, each of the memory (cells 140 and 145 can be implemented as a 1-transistor-1-resistor (1T1R) structure, e.g., a resistor with variable resistance serially connected to a transistor. Each of the memory cells 140 and 145 may be coupled to a corresponding word line WL, a corresponding bit line BL, and a corresponding source line SL. For example, each of the memory cells 140 and 145 is disposed at the interaction of a corresponding word line WL and the combination of a corresponding bit line BL and a corresponding source line SL.

As shown in the illustrative example of FIG. 1, the upper memory array 110 includes a number of word lines WL_{U}s, e.g., WL_{U}[0], WL_{U}[1] . . . WL_{U}[Y−1] disposed across multiple array rows, respectively, and the lower memory array 115 includes a number of word lines WL_{L}s, e.g., WL_{L}[0], WL_{L}[1] . . . WL_{L}[Y−1] disposed across multiple array rows, respectively. The number “Y” can be any integer. It should be understood that the numbers of word lines WLs (or rows) of the memory arrays 110 and 115 can be different. Each of the word lines WLs (WL_{U}[0] to WL_{U}[Y−1] and WL_{L}[0] to WL_{L}[Y−1]) can extend in the second lateral direction. The upper memory array 110 further includes a number of bit lines BL_{U}s, e.g., BL_{U}[0], BL_{U}[1] . . . BL_{U}[X−1], and a number of source lines SL_{U}s, e.g., SL_{U}[0], SL_{U}[0] . . . SL_{U}[X−1], disposed across multiple array columns, respectively, and the lower memory array 115 includes a number of bit lines BL_{L}S, e.g., BL_{L}[0], BL_{L}[1] . . . BL_{L}[X−1], and a number of source lines SL_{L}s, e.g., SL_{L}[0], SL_{L}[0] . . . SL_{L}[K−1], disposed across multiple array columns, respectively. The number “X” can be any integer. It should be understood that the numbers of bit lines BLs/source lines SLs (or columns) of the memory arrays 110 and 115 can be different. Each of the bit lines BLs (BL_{U}[0] to BL_{U}[X−1] and BL_{L}[0] to BL_{L}[X−1]) and the source lines SLs (SL_{U}[0] to SL_{U}[X−1] and SL_{L}[0] to SL_{L}[X−1]) can extend in the first lateral direction perpendicular to the second lateral direction.

The memory controller 140 is a hardware component that can control (e.g., read, write) operations of the upper memory array 110 through the WL driver circuit 120 and/or the I/O circuit 130, and control (e.g., read, write) operations of the lower memory array 115 through the WL driver circuit 125 and/or the I/O circuit 130. The WL driver circuits 120 and 125 and the I/O circuit 130 may each be embodied as one or more logic circuits, one or more analog circuits, or a combination of them. In some embodiments, the WL driver circuits 120 and 125 can each include a circuit configured to provide a voltage or current (e.g., a WL assertion signal with one or more pulses) through an asserted one of the word lines WLs of the memory array. The I/O circuit 130 can include a circuit configured to provide or sense a voltage or current through the respective bit lines BLs of the memory arrays 110 and 115. Further, the I/O circuit 130 can include a circuit configured as a current source coupled to the memory arrays 110 and 115 through their respective source lines SLs. In some other embodiments, the memory circuit 100 can include more, fewer, or different components than shown in FIG. 1. For example, the memory circuit 100 can further include a timing controller that can provide control signals or clock signals to synchronize operations of the WL driver circuits 120-125 and the I/O circuit 130.

As will be discussed below, some of the memory cells 140 of the upper memory array 110 can be configured as nominal memory cells (sometimes referred to as nominal memory cells 140_{N}) that store respective data bits, and some of the memory cells 140 of the upper memory array 110 can be configured as reference memory cells (sometimes referred to as reference memory cells 140_{R}) that store respective reference values. Similarly, some of the memory cells 145 of the lower memory array 115 can be configured as nominal memory cells (sometimes referred to as nominal memory cells 145_{N}) that store respective data bits, and some of the memory cells 145 of the lower memory array 115 can be configured as reference memory cells (sometimes referred to as reference memory cells 145_{R}) that store respective reference values. In accordance with various embodiments of the present disclosure, the reference memory cells 140_{R} and 145_{R} can be included in any of the above-mentioned global reference memory cell set, segmented reference memory cell set, or local reference memory cell set, and the nominal memory cells 140_{N} and 145_{N} can be included in the above-mentioned quasi-reference memory cell set.

FIG. 2 illustrates an example circuit diagram of the memory cell 140 or 145 (FIG. 1), in accordance with some embodiments of the present disclosure. In FIG. 2, the memory cell 140/145 includes a selector transistor and a variable resistor connected in series (sometimes referred to as a “1T1R” configuration), in some embodiments. It, however, should be appreciated that the circuit diagram of FIG. 2 is provided merely for illustrative purpose, and does not intend to limit the scope of the present disclosure.

As shown, the memory cell 140/145 includes a variable resistor 210 and a selector transistor 220 that are connected in series. The variable resistor 210 can present a resistance state that is switchable or programmable between a low resistance state (LRS) and a high resistance state (HRS). The resistance state can be indicative of a data value (e.g., logic “1” or logic “0”) stored by the memory cell 140/145. Programming the memory cell 140/145 into the HRS (e.g., logic 0) is sometimes referred to as performing a RESET operation, and programming the memory cell 140/145 into the LRS (e.g., logic 1) is sometimes referred to as performing a SET operation.

Further, a first terminal of the variable resistor 210 is connected to a bit line BL, a second terminal of the variable resistor 210 is connected to a first source/drain terminal of the selector transistor 220, a gate terminal of the selector transistor 220 is connected to a word line WL, and a second source/drain terminal of the selector transistor 220 is connected to a source line SL which is typically connected to ground. With this configuration, the selector transistor 220 can be activated (e.g., turned on) by asserting the word line WL such as, for example, applying a signal with logic 1 on the gate terminal of the selector transistor 220. Upen being activated, another signal can be applied or present on the bit line BL to read or write the variable resistor 210.

For example, during a read operation of the memory cell 140/145, a current may flow from the source SL, through the activated selector transistor 220 and the variable resistor 210, to the bit line BL. When programmed at the LRS, the current may be relatively high; and when programmed at the HRS, the current may be relatively low. The current may be provided to a sense amplifier (of the I/O circuit 130) that can compare the current to a reference value (e.g., a reference current) from a reference memory cell or an enlisted nominal memory cell. The reference memory cell may have a resistance that is an average of the HRS and LRS, which can be used a reference value. The sense amplifier can then compare the current output from the selected nominal memory cell against the current output from the reference memory cell/enlisted nominal memory cell, so as to determine whether a data bit stored by the selected nominal memory cell is equal to logic 0 or logic 1.

The variable resistor 210 typically includes a resistive switching element/variable resistive dielectric layer sandwiched between a top electrode and a bottom electrode. In some embodiments, the top electrode comprises titanium (Ti) and tantalum nitride (TaN), the bottom electrode comprises titanium nitride (TiN), and the variable resistive dielectric layer comprises nickel oxide (NiO), titanium oxide (TiO), hafnium oxide (HfO), zirconium oxide (ZrO), zinc oxide (ZnO), tungsten oxide (WO₃), aluminum oxide (Al₂O₃), tantalum oxide (TaO), molybdenum oxide (MoO), or copper oxide (CuO), for example. In some embodiments, the bottom electrode can be formed in a lower one of the metallization layers, and the top electrode can be formed in a higher one of the metallization layers. Further, a top electrode via (TEVA) can be formed over the top electrode, and a bottom electrode via (BEVA) can be formed below the bottom electrode, allowing the variable resistor 210 to connect to other structures/components such as, for example, the selector transistor 220, the bit line BL, etc.

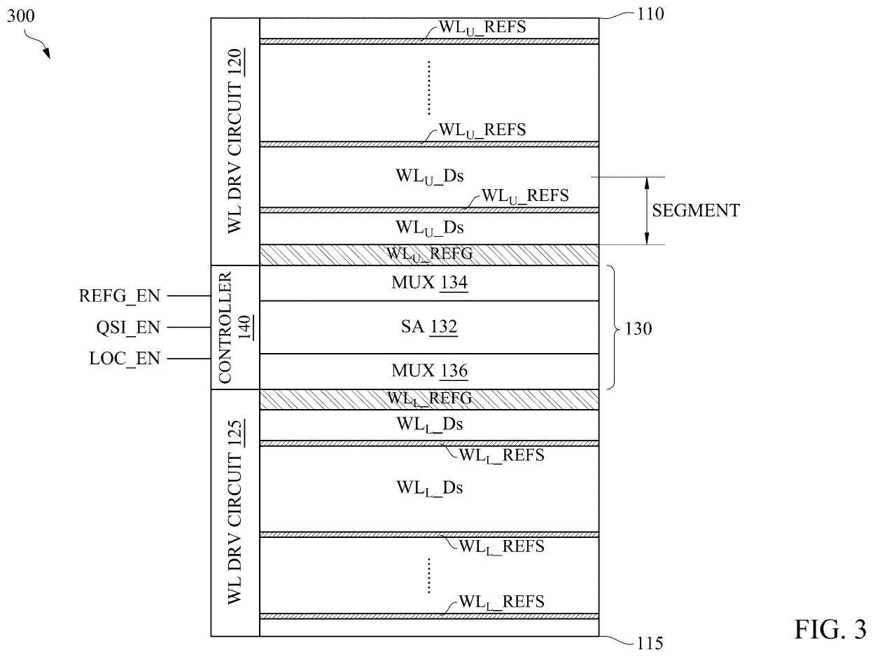

FIG. 3 illustrates an example schematic diagram of the memory circuit 100 shown in FIG. 1, in accordance with some embodiments. Hereinafter, the example of FIG. 3 is referred to as memory circuit 300. It should be understood that the schematic diagram of FIG. 3 is provided for illustrative purposes, and does not intend to limit the scope of the present disclosure. Accordingly, the memory circuit 300 can include any of various other suitable components, while remaining within the scope of the present disclosure.

As shown, the I/O circuit 130 can include a sense amplifier 132, a first multiplexer 134, and a second multiplexer 136. The sense amplifier 132 can be operatively coupled to the upper memory array 110 through the first multiplexer 134, and operatively coupled to the lower memory array 115 through the second multiplexer 136. Further, the sense amplifier 132 can be coupled to the memory cells 140 through the bit lines BLs of the upper memory array 110, and coupled to the memory cells 145 through the bit lines BLs of the lower memory array 115. The bit lines BLs of the upper and lower memory arrays, 110 and 115, extend along the Y-axis. As a non-limiting example, the number of bit lines BLs of each of the upper and lower memory arrays, coupled to one sense amplifier 132, may be equal to 32.

Each of the upper memory array 110 and the lower memory array 115 of the memory circuit 300 includes a plural number of data word lines WLs extending along the X-axis. In a non-limiting example, the memory array 110 can include 512 data word lines WL_{U}s (WL_{U}_Ds), and the memory array 115 can include 512 data word lines WL_{L}s (WL_{L}_Ds). Each of the data word lines WL_{U}_Ds can be coupled to a set of the nominal memory cells 140_{N} that are configured to store respective data bits, and each of the data word lines WL_{L}_Ds can be coupled to a set of the nominal memory cells 145_{N} that are configured to store respective data bits. The number of the set of nominal memory cells 140_{N}/145_{N} coupled to each of the data word lines WL_{U}_Ds/WL_{L}_Ds can be equal to the number of the bit lines BLs (or source lines SLs), e.g., 32.

Each of the upper memory array 110 and the lower memory array 115 of the memory circuit 300 includes a plural number of segmented reference word lines WLs extending along the X-axis. Over each of the memory arrays, the segmented reference word lines WLs may be disposed along the Y-axis with an interval of a predefined number (N) of the data word lines WL_Ds. Stated another way, each of the segmented reference word lines WLs may be disposed at the middle of a respective set of the data word lines WL_Ds (along the Y-axis), the number of which is equal to N. Such a set of the data word lines WL_Ds is sometimes referred to as a data word line segment, a reference segment, or a segment. Equivalently, this N can also refer to as the number of data word lines WL_Ds in each segment of a memory array.

In a non-limiting example where the upper memory array 110 includes 512 data word lines WL_Ds and N=32, the upper memory array 110 can include 16 segmented reference word lines (WL_{U}_REFSs) or 16 segments, given 512/32=16. Further, with the 16 segmented reference word lines WL_{U}_REFSs each disposed in the middle of a corresponding one of the 16 segments, adjacent ones of the segmented reference word lines WL_{U}_REFSs are separated from each other with 32 (N) data word lines WL_{U}_Ds. Alternatively stated, the upper memory array 110 includes 16 sets of data word lines WL_{U}_Ds, and includes 16 segmented reference word lines WL_{U}_REFSs each disposed in the middle of a corresponding one of the 16 sets of data word lines WL_{U}_Ds.

Similarly, in the example where the lower memory array 115 includes 512 data word lines WL_Ds and N=32, the lower memory array 115 can include 16 segmented reference word lines (WL_{L}_REFSs) or 16 segments, and adjacent ones of the segmented reference word lines WL_{L}_REFSs are separated from each other with 32 (N) data word lines WL_{L}_Ds. Alternatively stated, the upper memory array 115 includes 16 sets of data word lines WL_{L}_Ds, and includes 16 segmented reference word lines WL_{L}_REFSs each disposed in the middle of a corresponding one of the 16 sets of data word lines WL_{L}_Ds. The segmented reference word lines (WL_{U}_REFSs/WL_{L}_REFSs) can each be numbered with a parameter (M), which can by any integer from 0 to 15, which will be discussed in further detail below.

In another non-limiting example where the upper and lower memory arrays each include 512 data word lines WL_Ds and N=16, the upper/lower memory array 110/115 can include 32 segmented reference word lines (WL_{U/L}_REFSs) or 32 segments (as 512/16=32), and adjacent ones of the segmented reference word lines WL_{U/L}_REFSs are separated from each other with 16 (N) data word lines WL_{U/L}_Ds. In yet another non-limiting example where the upper and lower memory arrays each include 512 data word lines WL_Ds and N=64, the upper/lower memory array 110/115 can include 8 segmented reference word lines (WL_{U/L}_REFSs) or 8 segments (as 512/64=8), and adjacent ones of the segmented reference word lines WL_{U/L}_REFSs are separated from each other with 64 (N) data word lines WL_{U/L}_Ds.

Each of the upper memory array 110 and the lower memory array 115 of the memory circuit 300 includes one global reference word line WL extending along the X-axis. The global reference word line WL may be disposed along an edge of the corresponding memory array extending along the X-axis. For example, the upper memory array 110 can include 1 global reference word line (WL_{U}_REFG) disposed at the edge closest to the I/O circuit 130 (along the Y-axis), and the lower memory array 115 can include 1 global reference word line (WL_{L}_REFG) disposed at the edge closest to the I/O circuit 130 (along the Y-axis).

In some embodiments, each of the segmented reference word lines WL_{U}_REFSs is coupled to a respective set of the reference memory cells 140_{R} (one of the segmented reference memory cell sets of the upper memory array 110) that are each configured to store a reference value, and each of the segmented reference word lines WL_{L}_REFSs is coupled to a respective set of the reference memory cells 145_{R} (one of the segmented reference memory cell sets of the lower memory array 115) that are each configured to store a reference value. In some embodiments, the global reference word line WL_{U}_REFG is coupled to a respective set of the reference memory cells 140_{R} (the global reference memory cell set of the upper memory array 110) that are each configured to store a reference value, and the global reference word line WL_{L}_REFG is coupled to a respective set of the reference memory cells 145_{R} (the global reference memory cell set of the lower memory array 115) that are each configured to store a reference value.

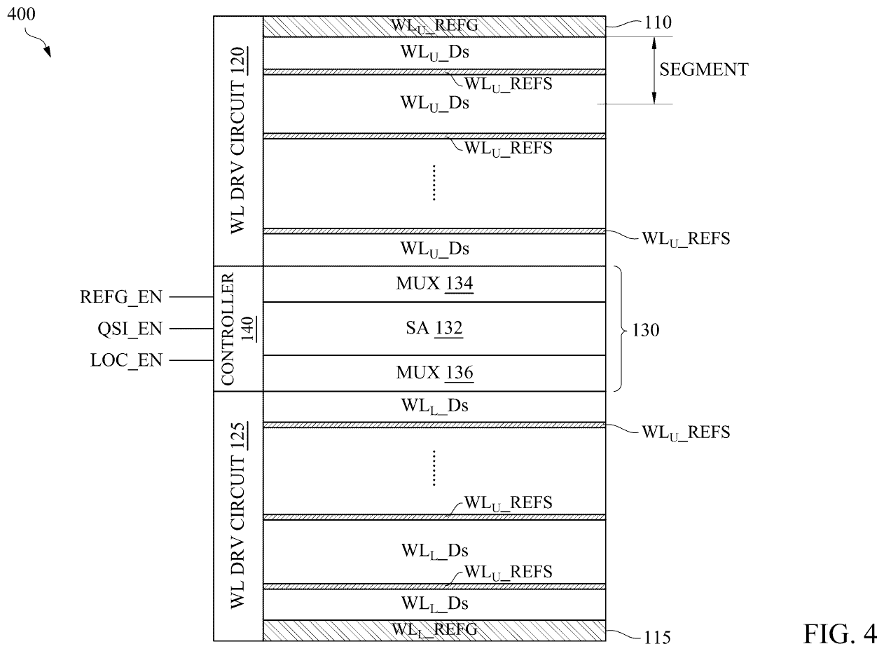

FIG. 4 illustrates another example schematic diagram of the memory circuit 100 shown in FIG. 1, in accordance with some embodiments. Hereinafter, the example of FIG. 4 is referred to as memory circuit 400. The memory circuit 400 is substantially similar to the memory circuit 300, except that the global reference word line WL_{U}_REFG is disposed at the edge of the memory array 110 farthest from the I/O circuit 130 (along the Y-axis) and the global reference word line WL_{L}_REFG is disposed at the edge of the memory array 115 farthest from the I/O circuit 130 (along the Y-axis). Accordingly, the description is not repeated.

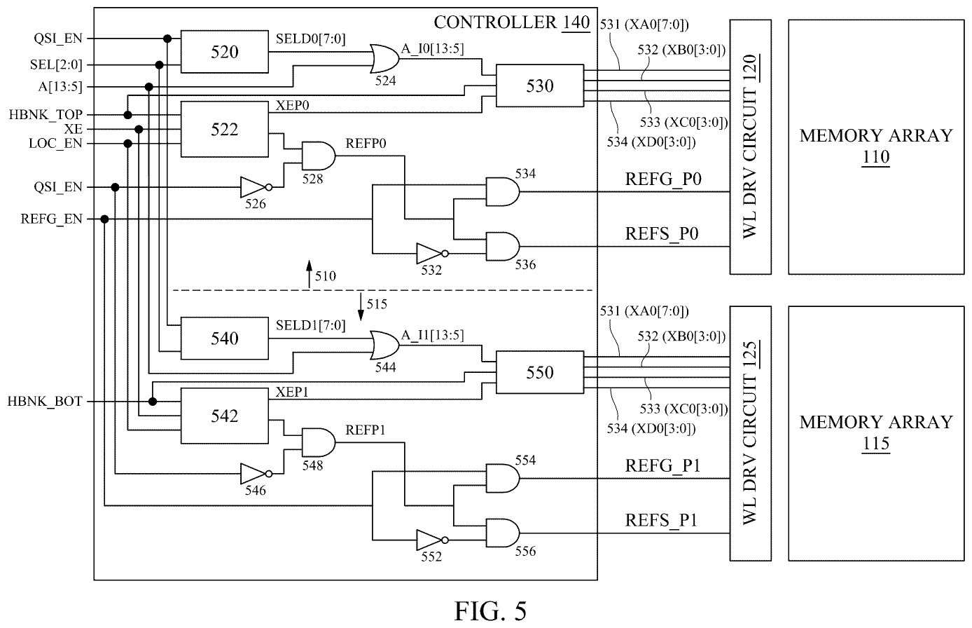

FIG. 5 illustrates an example circuit diagram of the memory controller 140 (FIG. 1), in accordance with some embodiments. In general, the memory controller 140 is configured to receive at least the control signals, e.g., the REFG_EN signal, the QSI_EN signal, the LOC_EN signal, etc., for determining a reference scheme applied while reading a nominal memory cell (e.g., 140_{N} or 145_{N}). According to some embodiments, the reference scheme can be one of a segmented reference scheme, a global reference scheme, a quasi-reference scheme, or a local reference scheme.

In the example circuit diagram of FIG. 5, the memory controller 140, coupled to the memory arrays 110 ad 115 through the WL driver circuits 120 and 125, respectively, includes an upper part 510 and a lower part 515. In some embodiments, the components of the upper part 510 and lower part 515 are substantially similar to each other, and thus, the following discussion will be focused on the difference. Further, the upper part 510 and lower part 515 can operatively share the REFG_EN signal, the QSI_EN signal, the LOC_EN signal, and some other control signals (e.g., A, SEL, XE, etc.), but receive respective certain control signals (e.g., HBNK_TOP and HBNK_BOT). It should be understood that the circuit diagram of FIG. 5 is provided for illustrative purposes, and does not intend to limit the scope of the present disclosure. Accordingly, the memory controller 140 can include any of various other suitable components, while remaining within the scope of the present disclosure.

The upper part 510 includes logic circuits 520, 522, 524, 526, 528, 530, 532, 534, and 536. The logic circuit 520 is configured to receive the QSI_EN signal and another signal (SEL[2:0]). The QSI_EN signal is configured to enable the quasi-reference scheme, and the SEL[2:0] signal is configured to indicate how many data word lines WL_D are included in a single segment while the quasi-reference scheme is enabled, which will be discussed below. The logic circuit 522 is configured to receive the LOC_EN signal, and at least another control signal (HBNK_TOP). The LOC_EN signal is configured to enable the local reference scheme, and the HBNK_TOP signal is configured to indicate whether to access (e.g., read) the data bits of the upper memory array 110. The logic circuit 524 (e.g., an OR gate) is configured to receive an address signal (A[13:5]) and an output (SELD0[8:0]) from the logic circuit 520. In some embodiments, all bits of the SELD signal are provided with logic 0, except for the quasi-reference scheme being applied, which will be discussed below. The logic circuit 530 (e.g., a decoder) is configured to receive an output (A_I0[13:5]) from the logic circuit 524, the HBNK_TOP signal, and one of the outputs (XEP0) from the logic circuit 522.

In some embodiments, the logic circuit 530 can provide a number of decoded signals, e.g., 531, 532, 533, and 534. In the example where the upper memory array 110 has 512 data word lines WL_{U}_Ds, the signal 534 (sometimes referred to as XD0[3:0]) is configured to identify one of 4 groups, each of which has 128 data word lines WL_{U}_Ds; on top of the 1 out of 4 groups of 128 WL_{U}_Ds being selected, the signal 533 (sometimes referred to as XC0[3:0]) is configured to identify one of 4 groups, each of which has 32 data word lines WL_{U}_Ds; on top of the 1 out of 4 groups of 32 WL_{U}_Ds being selected, the signal 532 (sometimes referred to as XB0[3:0]) is configured to identify one of 4 groups, each of which has 8 data word lines WL_{U}_Ds; and on top of the 1 out of 4 groups of 8 WL_{U}_Ds being selected, the signal 531 (sometimes referred to as XA0[7:0]) is configured to identify which of these 8 WL_{U}_Ds is selected or which corresponding WL driver (of the WL driver circuit 120) should be activated.

Referring still to the upper part 510 of the memory controller 140, the logic circuit 526 (e.g., an inverter) is configured to receive the QSI_EN signal. The logic circuit 528 (e.g., an AND gate) is configured to receive the other one of the outputs from the logic circuit 522 and an output of the logic circuit 526. The logic circuit 532 (e.g., an inverter) is configured to receive the REFG_EN signal. The logic circuit 534 (e.g., an AND gate) is configured to receive the REFG_EN signal and an output (REFP0) from the logic circuit 528. The logic circuit 536 (e.g., an AND gate) is configured to receive logically inverted version of the REFG_EN signal and the REFP0 signal. In some embodiments, the REFP signal (e.g., REFP0) may be provided with logic 0, if the corresponding memory array (e.g., 110) is configured to provide data bits. In other words, the REFP signal may be provided with logic 1, if the corresponding memory array is configured to provide reference values. In some embodiments, the logic circuit 534 is configured to generate an output (REFG_P0) that can indicate whether the global reference scheme is applied on the upper memory array 110; and the logic circuit 536 is configured to generate an output (REFS_P0) that can indicate whether the segmented reference scheme is applied on the upper memory array 110. Thus, if the REFP signal (e.g., REFP0) is provided with logic 0, then the REFG_P signal (e.g., REFG_P0) and the REFS_P (e.g., REFS_P0) are both outputted as logic 0 through the AND gates 534-536.

Similarly, the lower part 515 includes logic circuits 540, 542, 544, 546, 548, 550, 552, 554, and 556, which are substantially similar to the logic circuit 520, 522, 524, 526, 528, 530, 532, 534, and 536 of the upper part 510, respectively. The difference is that the logic circuit 542 (of the lower part 515) is configured to receive another control signal (HBNK_BOT), and the logic circuit 550 is configured to receive the HBNK_BOT signal. The HBNK_BOT signal is configured to indicate whether to access (e.g., read) the data bits of the lower memory array 115. In some embodiments, the HBNK_TOP signal and the HBNK_BOT signal are logically inverse to each other, when the segmented or global reference scheme is applied. For example, the HBNK_TOP signal and the HBNK_BOT signal may be provided at logic 1 and logic 0, respectively, causing the nominal memory cells 140_{N} of the upper memory array 110 to provide data bits, and the reference memory cells 145_{R} of the lower memory bank 115 to provide reference values. In another example, the HBNK_TOP signal and the HBNK_BOT signal may be provided at logic 0 and logic 1, respectively, causing the nominal memory cells 145_{N} of the lower memory array 115 to provide data bits, and the reference memory cells 140_{R} of the upper memory bank 110 to provide reference values.

Signals processed/outputted by the logic circuits 540 to 550 of the lower part 515 are similar to the signals from the upper part 510. For purposes of illustration, the signals from the upper part 510 are numbered with “0,” e.g., SELD0[8:0], XEP0, REFP0, A_I0[13:5], REFG_P0, REFS_P0, XA0[7:0], XB0[3:0], XC0[3:0], and XD0[3:0]; and the signals from the lower part 515 are numbered with “1,” e.g., SELD1[8:0], XEP1, REFP1, A_I1[13:5], REFG_P1, REFS_P1, XA1[7:0], XB1[3:0], XC1[3:0], and XD1[3:0]. Sometimes, XA1[7:0], XB1[3:0], XC1[3:0], and XD1[3:0] are referred to as signals 554, 553, 552, and 551, respectively.

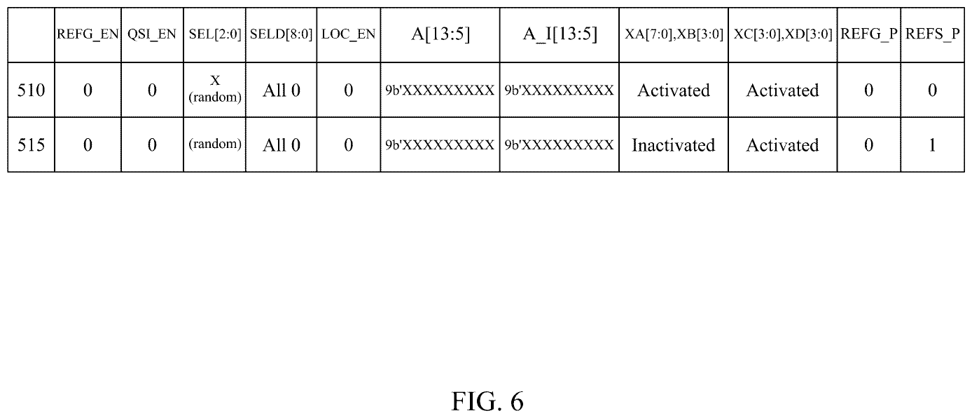

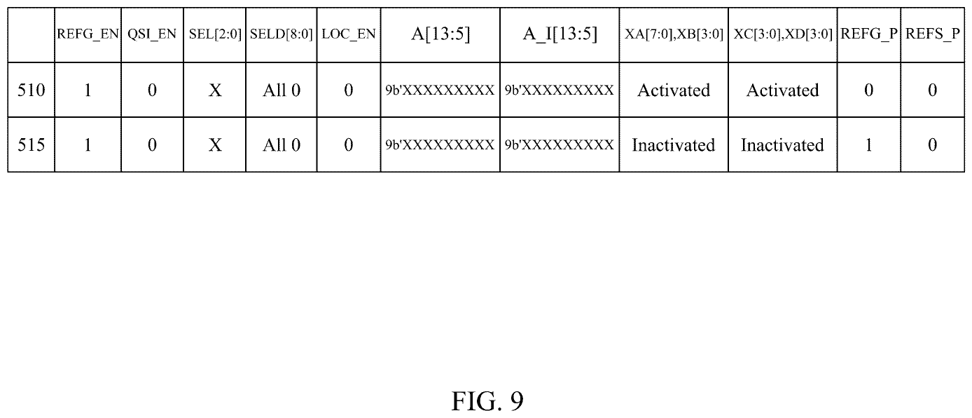

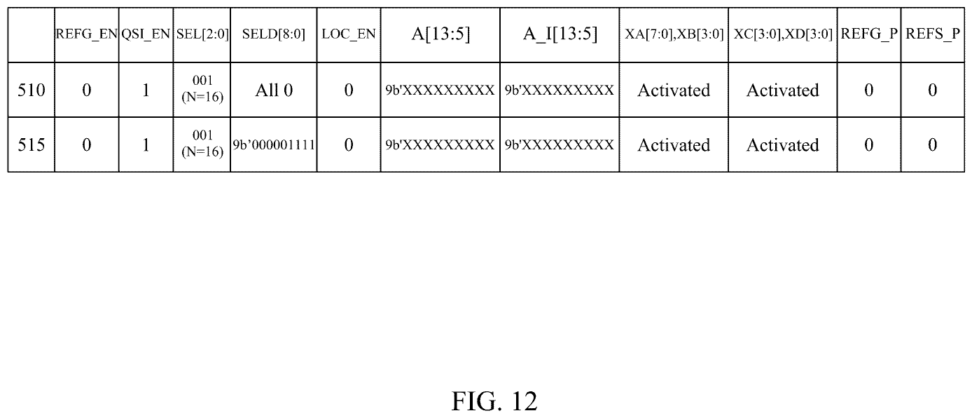

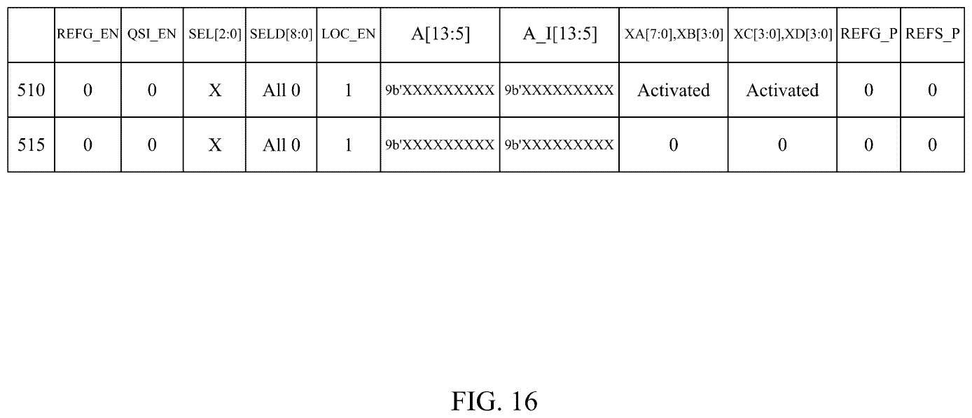

According to some embodiments of the present disclosure, based on different logic combinations of the foregoing control signals (e.g., the REFG_EN signal, the QSI_EN signal, the LOC_EN signal), the memory controller 140 can apply respective reference schemes to the memory array 110 or 115. For example, in the following discussion, FIGS. 6 to 8, with the REFG_EN signal, the QSI_EN signal, the LOC_EN signal respectively provided as logic 0, logic 0, and logic 0, provide an example where the segmented reference scheme is applied; FIGS. 9 to 11, with the REFG_EN signal, the QSI_EN signal, the LOC_EN signal respectively provided as logic 1, logic 0, and logic 0, provide an example where the global reference scheme is applied; FIGS. 12 to 15, with the REFG_EN signal, the QSI_EN signal, the LOC_EN signal respectively provided as logic 0, logic 1, and logic 0, provide an example where the quasi-reference scheme is applied; and FIGS. 16 to 18, with the REFG_EN signal, the QSI_EN signal, the LOC_EN signal respectively provided as logic 0, logic 0, and logic 1, provide an example where the local reference scheme is applied.

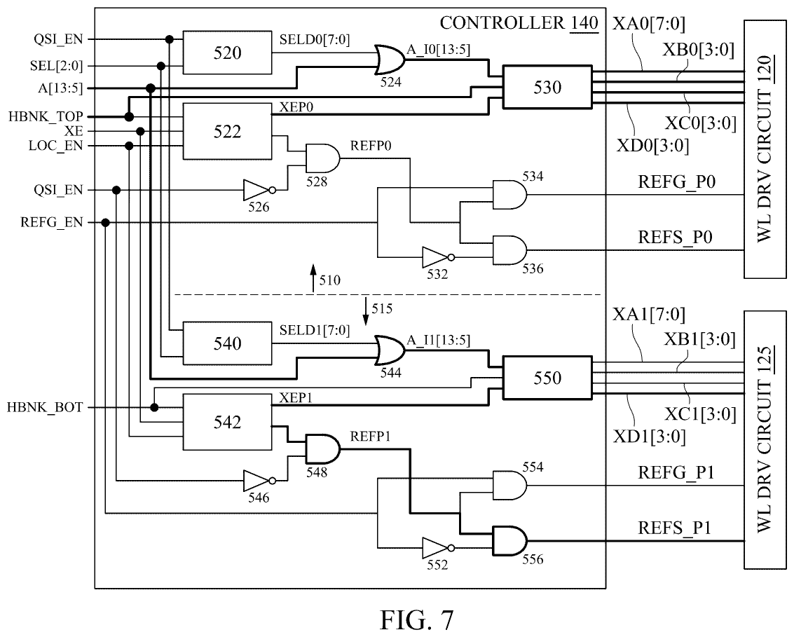

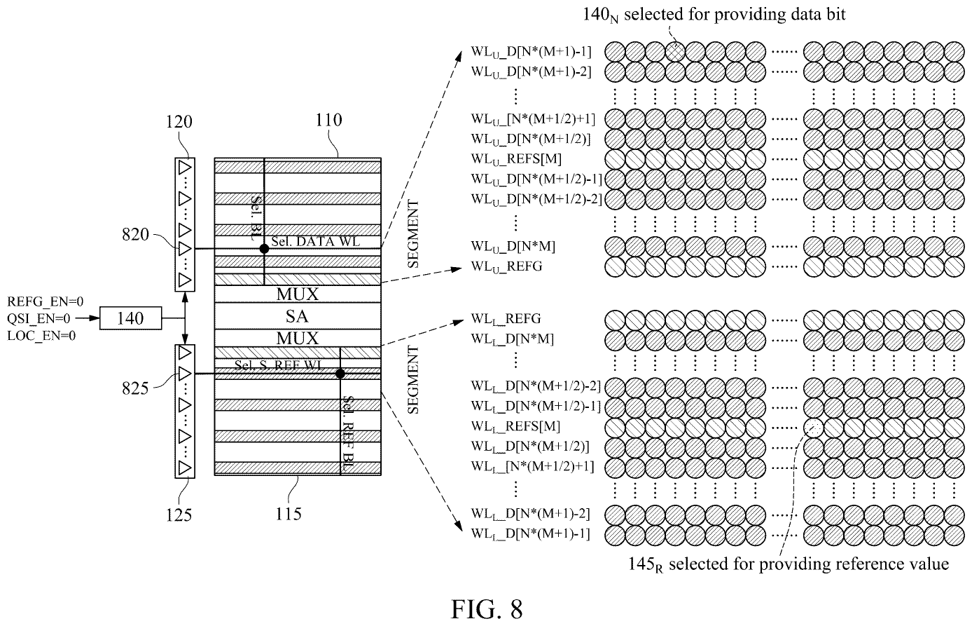

Referring first to FIG. 6 (in conjunction with FIGS. 7-8), a table summarizing respective logic values of the REFG_EN signal, the QSI_EN signal, and the LOC_EN signal, corresponding to the segmented reference scheme, and other (intermediate or output) signals are provided. The first row and the second row of the table refer to the signals present in the upper part 510 and lower part 515, respectively. As shown, the REFG_EN signal, the QSI_EN signal, the LOC_EN signal are respectively provided as logic 0, logic 0, and logic 0. Such a logic combination of the REFG_EN signal, the QSI_EN signal, the LOC_EN can activate or otherwise functionalize certain logic circuits of the memory controller 140, for example, 520, 522, 524, 530, 540, 542, 544, 550, 548, and 556, as highlighted in FIG. 7 which annotates the circuit diagram of the memory controller 140 (FIG. 5). In the example of FIGS. 6-8, the HBNK_TOP signal and the HBNK_BOT signal are provided with logic 1 and logic 0, respectively, causing the upper memory array 110 to provide a data bit and the lower memory array 115 to provide a reference value.

As shown in FIGS. 6-7, the decoded signals provided to the WL driver circuit 120, XA0 to XD0, are all activated, while the decoded signals provided to the WL driver circuit 125, XA1 to XD1, are partially activated. For example, only the XC1 and XD1 signals are activated. This is because when the segmented reference scheme is applied, only one segmented reference word line WL_REFS should be selected. Given the example where the above-mentioned N (the number of data word lines WL_Ds of each segment) is provided as 32, the lower memory array 115 can include 16 (=512/32) segments, each of which can include a segmented reference word line WL_REFS coupled to a respective segmented reference memory cell set. In order to select one of these 16 segments (or one of the 16 segmented reference word line WL_REFSs), the resolution can be provided simply by the XC1 and XD1 signals. With the HBNK_TOP signal, the HBNK_BOT signal, the LOC_EN signal, and the QSI_EN signal are provided with logic 1, logic 0, logic 0, and logic 0, respectively, the logic circuits 542 to 548 can provide the REFP1 signal at logic 1. With the REFG_EN signal provided at logic 0, through the logic circuit 552, the logic circuit 556 can provide the REFS_P1 at logic 1. Together with the decoded address signals (XC1 and XD1 signals), one of the drivers of the WL driver circuit 125, operatively coupled to the segmented reference word line WL_REFS of the selected segment, can be activated. This activated driver can thus assert the segmented reference word line WL_REFS of the selected segment.

In some embodiments, each of the upper memory array 110 and the lower memory array 115 share the same segmentary arrangement. For example, when N is provided as 32, the upper memory array 110 and the lower memory array 115, each with 512 data word lines WL_Ds, both have 16 segments. Each of these 16 segments has 32 data word lines WL_Ds, with a segmented reference word line WL_REFS disposed in the middle thereof. Further, each of these 16 segments (or the included segmented reference word line WL_REFS) can be numbered by the parameter M, which can be any integer of 0 to 15. Further, in some embodiments, the memory controller 140 may apply the same parameter M on both the memory array 110 (e.g., configured to provide a data bit) and the memory array 115 (e.g., configured to provide a reference value). For example, when a nominal memory cell disposed along one of the data word lines WL_Ds (in the M^{th} segment) among one of the memory arrays 110 or 115 is selected to be read out its data bit, the memory controller 140 can select a reference memory cell disposed along the segmented reference word line WL_REFS of the M^{th} segment among the other of the memory arrays 110 or 115 to provide a reference value.

FIG. 8 illustrates an example where a data bit of one nominal memory cell 140_{N} of the upper memory array 110 is selected to be read, while a reference value of one reference memory cell 145_{R} of the lower memory array 115 is used for comparing with the data bit. In FIG. 8, each circle corresponds to one of the memory cells 140 or 145. As shown, one nominal memory cell 140_{N} coupled to a data word line WL_{U}_D, referenced as WL_{U}_D[N×(M+1)−1], is selected to be read by activating one of the drivers of the WL driver circuit 120 (e.g., driver 820 in FIG. 8). In some embodiments, the memory controller 140 can select one reference memory cell 145_{R}, coupled to a segmented reference word line WL_{L}_REFS, referenced as WL_{L}_REFS[M], to provide its reference value by activating one of the drivers of the WL driver circuit 125 (e.g., driver 825 in FIG. 8). In some embodiments, each of the word lines (WL_{U}_Ds, WL_{U}_REFSs, WL_{U}_REFG) of the upper memory array 110 can be coupled to a respective one of plural drivers of the WL driver circuit 120, and each of the word lines (WL_{L}_Ds, WL_{L}_REFSs, WL_{L}_REFG) of the lower memory array 115 can be coupled to a respective one of plural drivers of the WL driver circuit 125. It should be noted that when any of the nominal memory cell 140_{N} in the M^{th} segment of the array 110 (i.e., coupled to other data word lines WL_{U}_D such as, WL_{U}_D[N×(M+1)−2] to WL_{U}_D[N×M]), the memory controller 140 may still select one of the reference memory cells 145_{R} coupled to the WL_{L}_REFS[M].

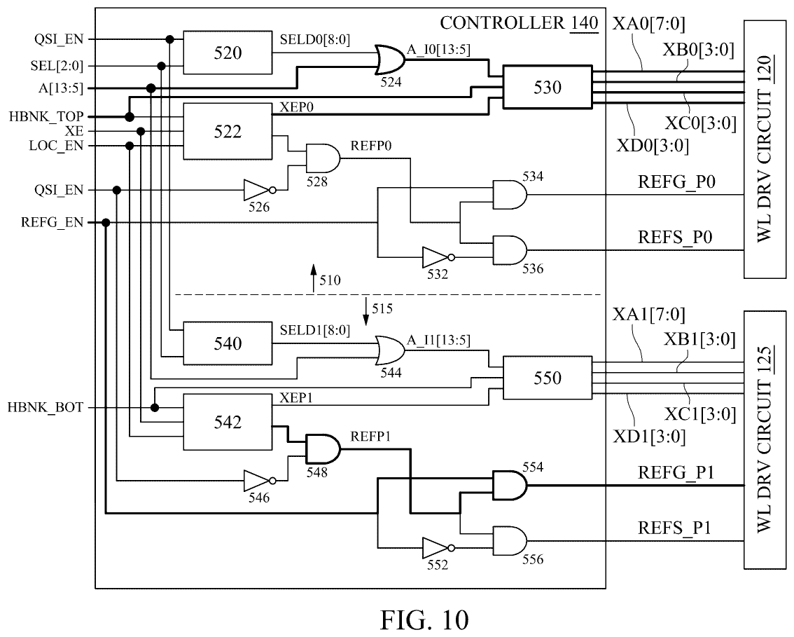

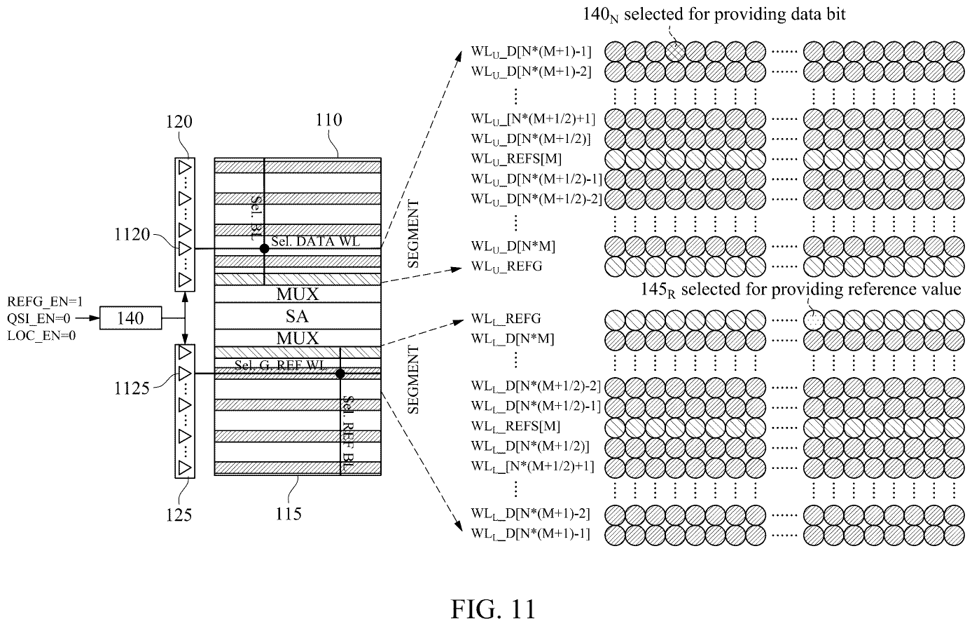

Referring next to FIG. 9 (in conjunction with FIGS. 10-11), a table summarizing respective logic values of the REFG_EN signal, the QSI_EN signal, and the LOC_EN signal, corresponding to the global reference scheme, and other (intermediate or output) signals are provided. The first row and the second row of the table refer to the signals present in the upper part 510 and lower part 515, respectively. As shown, the REFG_EN signal, the QSI_EN signal, the LOC_EN signal are respectively provided as logic 1, logic 0, and logic 0. Such a logic combination of the REFG_EN signal, the QSI_EN signal, the LOC_EN can activate or otherwise functionalize certain logic circuits of the memory controller 140, for example, 520, 522, 524, 530, 540, 542, 544, 548, 550, and 554, as highlighted in FIG. 10 which annotates the circuit diagram of the memory controller 140 (FIG. 5). In the example of FIGS. 9-11, the HBNK_TOP signal and the HBNK_BOT signal are provided with logic 1 and logic 0, respectively, causing the upper memory array 110 to provide a data bit and the lower memory array 115 to provide a reference value.

As shown in FIGS. 9-10, the decoded signals provided to the WL driver circuit 120, XA0 to XD0, are all activated, while the decoded signals provided to the WL driver circuit 125, XA1 to XD1, are all inactivated. This is because when the global reference scheme is applied, only the global reference word line WL_REFG should be selected. That is, no segment should be selected. With the HBNK_TOP signal, the HBNK_BOT signal, the LOC_EN signal, and the QSI_EN signal are provided with logic 1, logic 0, logic 0, and logic 0, respectively, the logic circuits 542 to 548 can provide the REFP1 signal at logic 1. With the REFG_EN signal provided at logic 1, the logic circuit 554 can provide the REFG_P1 signal at logic 1. Together with the decoded address signals (XA1 to XD1 signals) all deactivated, one of the drivers of the WL driver circuit 125, operatively coupled to the global reference word line WL_REFG, can be activated. This activated driver can thus assert the global reference word line WL_REFG.

FIG. 11 illustrates an example where a data bit of one nominal memory cell 140_{N} of the upper memory array 110 is selected to be read, while a reference value of one reference memory cell 145_{R} of the lower memory array 115 is used for comparing with the data bit. In FIG. 11, each circle corresponds to one of the memory cells 140 or 145. As shown, one nominal memory cell 140_{N} coupled to a data word line WL_{U}_D, referenced as WL_{U}_D[N×(M+1)−1], is selected to be read by activating one of the drivers of the WL driver circuit 120 (e.g., driver 1120 in FIG. 11). In some embodiments, the memory controller 140 can select one reference memory cell 145_{R}, coupled to the global reference word line WL_{L}_REFG, to provide its reference value by activating one of the drivers of the WL driver circuit 125 (e.g., driver 1125 in FIG. 11). In some embodiments, each of the word lines (WL_{U}_Ds, WL_{U}_REFSs, WL_{U}_REFG) of the upper memory array 110 can be coupled to a respective one of plural drivers of the WL driver circuit 120, and each of the word lines (WL_{L}_Ds, WL_{L}_REFSs, WL_{L}_REFG) of the lower memory array 115 can be coupled to a respective one of plural drivers of the WL driver circuit 125.

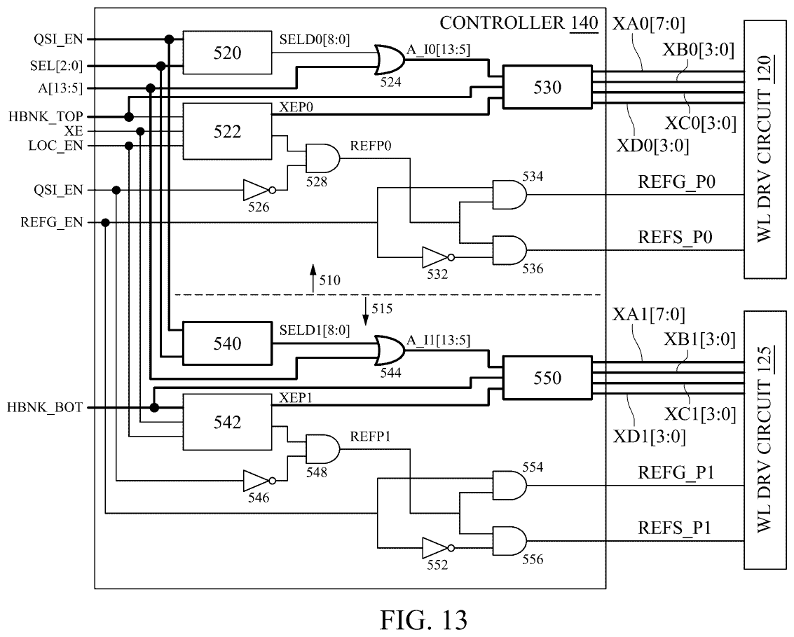

Referring next to FIG. 12 (in conjunction with FIGS. 13-15), a table summarizing respective logic values of the REFG_EN signal, the QSI_EN signal, and the LOC_EN signal, corresponding to the quasi-reference scheme, and other (intermediate or output) signals are provided. The first row and the second row of the table refer to the signals present in the upper part 510 and lower part 515, respectively. As shown, the REFG_EN signal, the QSI_EN signal, the LOC_EN signal are respectively provided as logic 0, logic 1, and logic 0. Such a logic combination of the REFG_EN signal, the QSI_EN signal, the LOC_EN can activate or otherwise functionalize certain logic circuits of the memory controller 140, for example, 520, 522, 524, 530, 540, 542, 544, and 550, as highlighted in FIG. 13 which annotates the circuit diagram of the memory controller 140 (FIG. 5). In the example of FIGS. 12-13, the HBNK_TOP signal and the HBNK_BOT signal are both provided with logic 1, causing the upper memory array 110 to provide a data bit and the lower memory array 115 to repurpose or enlist one of its memory cells 145_{N} for providing a reference value.

As shown in FIGS. 12-13, the decoded signals provided to the WL driver circuit 120, XA0 to XD0, are all activated, and the decoded signals provided to the WL driver circuit 125, XA1 to XD1, are all activated as well. This is because when the quasi-reference scheme is applied, any of the data word lines WL_Ds of the memory array that is configured to provide a reference value can be selected. With the HBNK_TOP signal and the HBNK_BOT signal are both provided with logic 1, the logic circuits 528 and 548 can provide the REFP0 signal and the REFP1 signal at logic 0, which in turn provides the REFG_P0 signal, REFS_P0 signal, REFG_P1 signal, and REFS_P1 signal at logic 0. That is, no global reference memory cell set or segmented reference memory cell set in either of the upper memory array 110 or the lower memory array 115 will be activated.

Further, when the quasi-reference scheme is applied (e.g., by providing the QSI_EN signal at logic 1), the SEL[2:0] signal should be provided to indicate the value of above-mentioned N, in some embodiments. The SEL[2:0] signal can indicate up to 8 different values of N. For example, when SEL[2:0]=(000), N=1; when SEL[2:0]=(001), N=16; when SEL[2:0]=(010), N=32; when SEL[2:0]=(011), N=64; and when SEL[2:0]=(100), N=512. With N specified, the number of each segment (of the data word lines WL_Ds) can be determined. In the example of FIG. 12, SEL[2:0] is provided as (001) and accordingly N is provided as 16. In some embodiments, the memory controller 140 can divide the data word lines of the memory array configured to provide the reference value (e.g., 115) into 32 (512/16) segments. Each of these segments is numbered by the parameter M.

Continuing with the example where a memory array has 512 data word lines WL_Ds and N=16, the memory array can have 32 segments, each of which is referenced by M. Accordingly, M can be any integer from 0 to 31. Given 512 data word lines WL_Ds in each memory array, Table I below shows different combinations of the SEL[2:0] signal (e.g., corresponding to N) and their corresponding segmentary values (e.g., the range of M, the number of data word lines in each segment, the number of segment, etc.).

TABLE I

| | | Range | # of data WLs in | # of |
|---|---|---|---|---|
| SEL[2:0] | N | of M | each segment | segments |
| 000 | 1 | 0~511 | 1 | 512 |
| 001 | 16 | 0~31 | 16 | 32 |
| 010 | 32 | 0~15 | 32 | 16 |
| 8011 | 64 | 0~7 | 64 | 8 |
| 100 | 512 | 0 | 512 | 1 |

In some embodiments, based on the SEL[2:0] signal to determine N and the address signal (e.g., A[13:5]) to select one of the data word lines WL_{U}_Ds of one of the memory arrays (e.g., 110) to provide a data bit, the memory controller 140 can identify the value of the parameter M. Stated another way, the memory controller 140 can identify the M^{th} segment to which the data word line WL_{U}_D belongs. Next, the memory controller 140 can use the value of the parameter M to select which segment of the data word lines WL_{L}_Ds of the other of the memory arrays (e.g., 115) for providing a reference value. The memory controller 140 can select the M^{th} segment of the memory array 115. Further, the memory controller 140 can select a data word line WL_{L}_D within the M^{th} segment of the memory array 115 based on a most significant bit (MSB) of N.

For example, when the data word line WL_{U}_D[0] (of the memory array 110) is selected for providing a data bit and N is provided as 1, a value of the parameter M is determined as 0. That is, the 0^{th} segment of the memory array 110 is selected. Next, the memory controller 140 can select the 0^{th} segment of the memory array 115 and further select the data word line WL_{L}_D[0] (within the 0^{th} segment of the memory array 115) for providing a reference value. In another example, when the data word line WL_{U}_D[0] (of the memory array 110) is selected for providing a data bit and N is provided as 16, a value of the parameter M is determined as 0 (the 0^{th} segment of the memory array 110). The memory controller 140 can select the 0^{th} segment of the memory array 115 and further select the data word line WL_{L}_D[15] (within the 0^{th} segment of the memory array 115) for providing a reference value. In yet another example, when the data word line WL_{U}_D[0] (of the memory array 110) is selected for providing a data bit and N is provided as 32, a value of the parameter M is determined as 0 (the 0^{th} segment of the memory array 110). The memory controller 140 can select the 0^{th} segment of the memory array 115 and further select the data word line WL_{L}_D[31] (within the 0^{th} segment of the memory array 115) for providing a reference value.

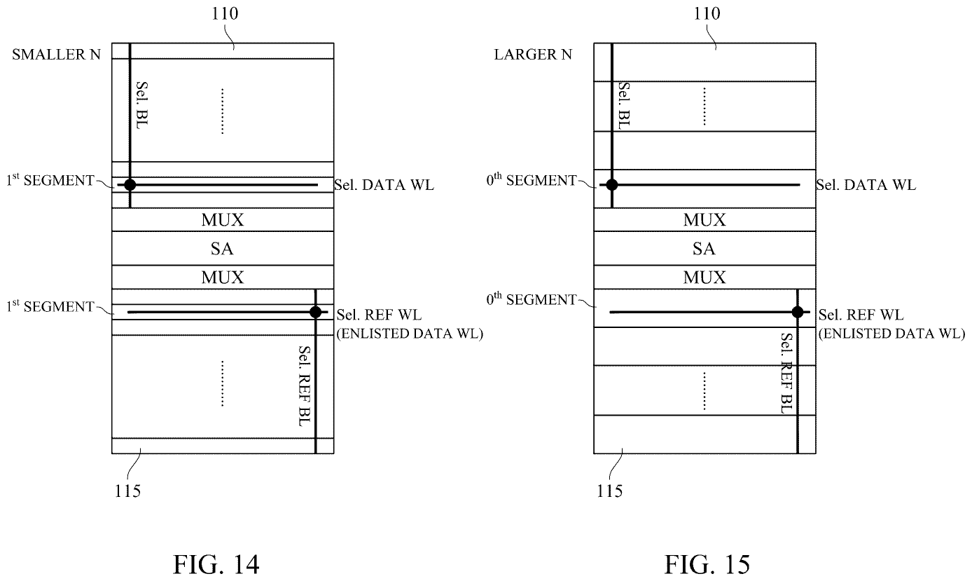

FIG. 14 and FIG. 15 respectively illustrate examples where different values of N (e.g., through the SEL[2:0] signal) are provided. For purposes of clarity, in FIG. 14 or 15, no segmented or global reference word line is shown in the memory array 110 or 115. In FIG. 14, N is provided with a smaller value, while, in FIG. 15, N is provided with a larger value. Further, in FIG. 14, once a nominal memory cell 140_{N} of the 1^{st} segment of the upper memory array 110 is selected for providing a data bit, the 1^{st} segment of the lower memory array 115 is selected and a nominal memory cell 145_{N} coupled to an enlisted data word line WL_{L}_D within that 1^{st} segment of the lower memory array 115 is selected for providing a reference value; and in FIG. 15, once a nominal memory cell 140_{N} of the 0^{th} segment of the upper memory array 110 is selected for providing a data bit, the 0^{th} segment of the lower memory array 115 is selected and a nominal memory cell 145_{N} coupled to an enlisted data word line WL_{L}_D within that 0^{th} segment of the lower memory array 115 is selected for providing a reference value.

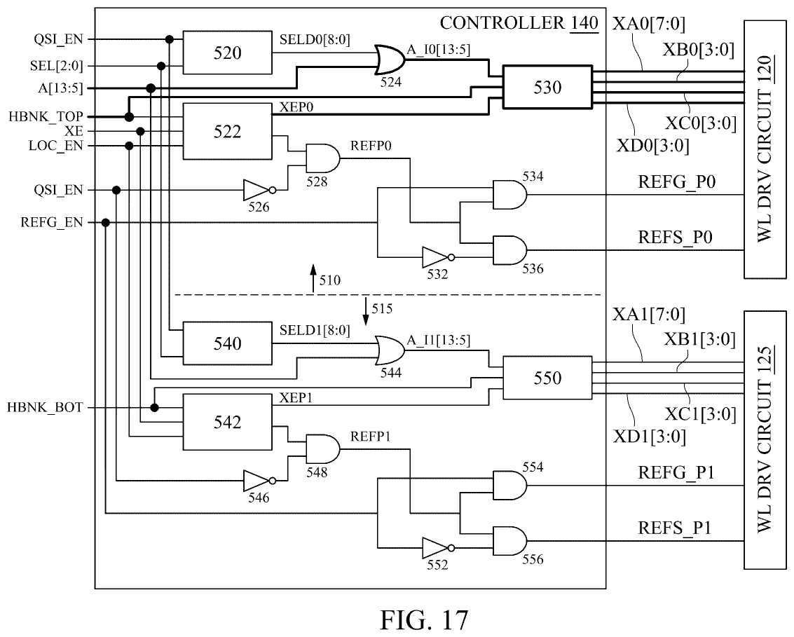

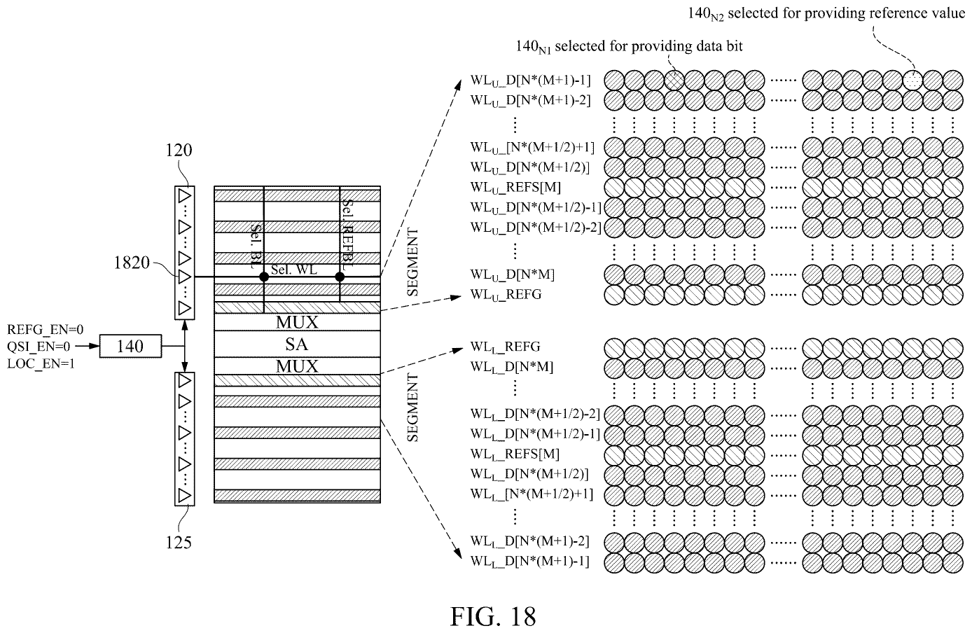

Referring next to FIG. 16 (in conjunction with FIGS. 17-18), a table summarizing respective logic values of the REFG_EN signal, the QSI_EN signal, and the LOC_EN signal, corresponding to the local reference scheme, and other (intermediate or output) signals are provided. The first row and the second row of the table refer to the signals present in the upper part 510 and lower part 515, respectively. As shown, the REFG_EN signal, the QSI_EN signal, the LOC_EN signal are respectively provided as logic 0, logic 0, and logic 1. Such a logic combination of the REFG_EN signal, the QSI_EN signal, the LOC_EN can activate or otherwise functionalize certain logic circuits of the memory controller 140, for example, 520, 522, 524, and 530, as highlighted in FIG. 17 which annotates the circuit diagram of the memory controller 140 (FIG. 5). In the example of FIGS. 16-81, the HBNK_TOP signal and the HBNK_BOT signal are provided with logic 1 and logic 0, respectively, causing the upper memory array 110 to provide a data bit and also a reference value.

As shown in FIGS. 16-17, the decoded signals provided to the WL driver circuit 120, XA0 to XD0, are all activated, while the decoded signals provided to the WL driver circuit 125, XA1 to XD1, are all inactivated. This is because when the local reference scheme is applied, one of the data word line WL_{U}_Ds should be selected for providing both the data bit and the reference value. That is, no segment should be selected. With the HBNK_TOP signal, the HBNK_BOT signal, the LOC_EN signal, and the QSI_EN signal are provided with logic 1, logic 0, logic 1, and logic 0, respectively, the logic circuits 542 to 548 can provide the REFP1 signal at logic 0. With the REFG_EN signal provided at logic 0, the logic circuits 554 and 556 can provide the REFG_P1 signal and REFS_P1 signal both at logic 0. Similarly, both the REFG_P0 signal and REFS_P0 signal are provided at logic 0. Together with the decoded address signals (XA0 to XD0 signals) all activated, one of the drivers of the WL driver circuit 120, operatively coupled to the data word line WL_{U}_D, can be activated. This activated driver can thus assert the date word line WL_{U}_D.

FIG. 18 illustrates an example where a data bit of one nominal memory cell 140_{N} (140_{N1}) of the upper memory array 110 is selected to be read and a data bit of another nominal memory cell 140_{N} (145_{N2}) of the upper memory array 110 is selected as a reference value. The reference value is used for comparing with the data bit. In FIG. 18, each circle corresponds to one of the memory cells 140 or 145. As shown, the memory cell 140_{N1} coupled to a data word line WL_{U}_D, referenced as WL_{U}_D[N×(M+1)−1], is selected to be read by activating one of the drivers of the WL driver circuit 120 (e.g., driver 1820 in FIG. 18). In some embodiments, the memory controller 140 can select the memory cell 145_{N2}, coupled to the same data word line WL_{U}_D[N×(M+1)−1], to provide its data bit as a reference value by activating the same driver. In some embodiments, each of the word lines (WL_{U}_Ds, WL_{U}_REFSs, WL_{U}_REFG) of the upper memory array 110 can be coupled to a respective one of plural drivers of the WL driver circuit 120, and each of the word lines (WL_{L}_Ds, WL_{L}_REFSs, WL_{L}_REFG) of the lower memory array 115 can be coupled to a respective one of plural drivers of the WL driver circuit 125.

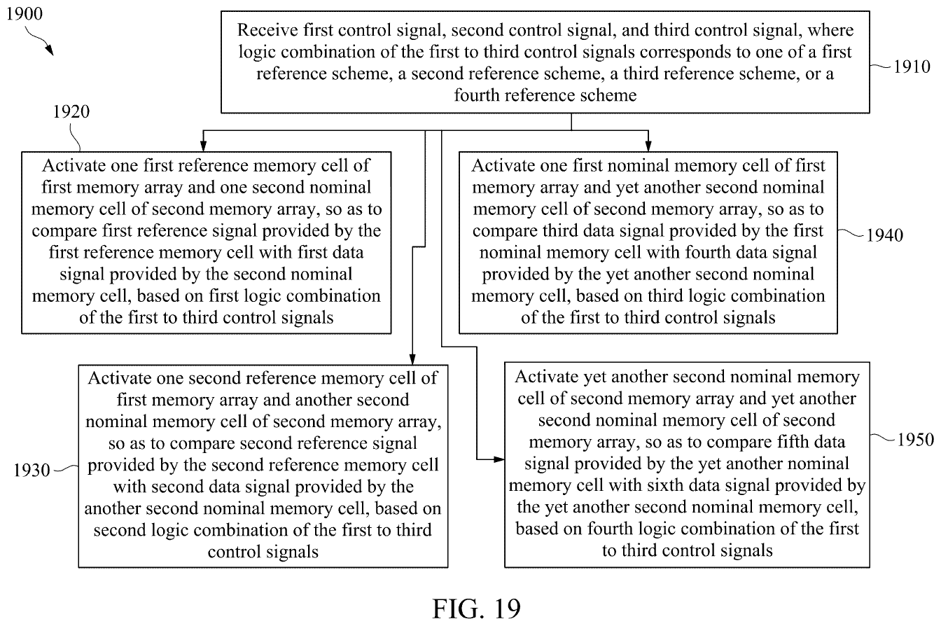

FIG. 19 illustrates a flowchart of an example method 1900 for operating a memory device including a memory controller configured to select one of various reference schemes while performing a read operation, in accordance with some embodiments. For example, at least some of the operations of the method 1900 can be performed by the memory controller 140 discussed with respect to FIGS. 1-18. Thus, in the following discussion of the method 1900, the reference numerals used at least in FIGS. 1-18) may be reused. It is noted that the method 1900 is merely an example and is not intended to limit the present disclosure. Accordingly, it is understood that additional operations may be provided before, during, and after the method 1900 of FIG. 19, and that some other operations may only be briefly described herein.

The method 1900 starts with operation 1910 of receiving a first control signal, a second control signal, and a third control signal. In some embodiments, a logic combination of the first to third control signals is configured to select one of a first reference scheme, a second reference scheme, a third reference scheme, or a fourth reference scheme. For example, the memory controller 140, coupled to the upper memory array 110 and the lower memory array 115 through the WL driver circuit 120 and the WL driver circuit 125, respectively, can receive the REFG_EN signal, the QSI_EN signal, and the LOC_EN signal. Based on the logic combination of the REFG_EN signal, the QSI_EN signal, and the LOC_EN signal, which corresponds to one of a segmented reference scheme, a global reference scheme, a quasi-reference scheme, or a local reference scheme, the memory controller 140 can activate a driver of the WL driver circuit 120 or the WL driver circuit 125 to assert a corresponding word line (e.g., WL_{U}_D, WL_{L}_D, WL_{U}_REFS, WL_{L}_REFS, WL_{U}_REFG, WL_{L}_REFG), so as to turn on a corresponding memory cell (e.g., 140_{N}, 140_{R}, 145_{N}, 145_{R}) to provide a reference value.

The method 1900 proceeds to operation 1920 of activating one of a plurality of first reference memory cells of a first memory array and one of a plurality of second nominal memory cells of a second memory array, so as to compare a first reference signal provided by the one of the first reference memory cells with a first data signal provided by the one of the second nominal memory cells, based on a first logic combination of the first to third control signals; the method 1900 proceeds to operation 1930 of activating one of a plurality of second reference memory cells of the first memory array and another of the plurality of second nominal memory cells of the second memory array, thereby comparing a second reference signal provided by the one of the second reference memory cells with a second data signal provided by the another of second nominal memory cells, based on a second logic combination of the first to third control signals; the method 1900 proceeds to operation 1940 of activating one of a plurality of first nominal memory cells of the first memory array and yet another of the plurality of second nominal memory cells of the second memory array, thereby comparing a third data signal provided by the one of the first nominal memory cells with a fourth data signal provided by the yet another of second nominal memory cells, based on a third logic combination of the first to third control signals; or the method 1900 proceeds to operation 1950 of activating yet another of the plurality of second nominal memory cells of the second memory array and yet another of the plurality of second nominal memory cells of the second memory array, thereby comparing a fifth data signal provided by the yet another of the second nominal memory cells with a sixth data signal provided by the yet another of second nominal memory cells, based on a fourth logic combination of the first to third control signals.

Continuing with the above example, the first and second memory arrays can be non-limiting examples of the lower memory array 115 and the upper memory array 110, respectively. Further, the first nominal memory cells can be the nominal memory cells 145_{N} coupled to one of the data word lines WL_{L}_Ds; the second nominal memory cells can be the nominal memory cells 140_{N} coupled to one of the data word lines WL_{U}_Ds; the first reference memory cells can be the reference memory cells 145_{R} coupled to one of the segmented reference word lines WL_{L}_REFSs; and the second reference memory cells can be the reference memory cells 145_{R} coupled to the global reference word line WL_{L}_REFG.

Further, in the operation 1920, the first logic combination of the first to third control signals can correspond to the segmented reference scheme. When the segmented reference scheme is applied by the memory controller 140, the memory controller 140 can compare a data signal provided by one of the nominal memory cells 140_{N} with a reference signal provided by one of the reference memory cells 145_{R} that is coupled to a corresponding one of the segmented reference word lines WL_{L}_REFSs. Details can be referred to the example illustrated in FIGS. 6-8.

In the operation 1930, the first logic combination of the first to third control signals can correspond to the global reference scheme. When the global reference scheme is applied by the memory controller 140, the memory controller 140 can compare a data signal provided by one of the nominal memory cells 140_{N} with a reference signal provided by one of the reference memory cells 145_{R} that is coupled to the global reference word line WL_{L}_REFG. Details can be referred to the example illustrated in FIGS. 9-11.

In the operation 1940, the first logic combination of the first to third control signals can correspond to the quasi-reference scheme. When the quasi-reference scheme is applied by the memory controller 140, the memory controller 140 can compare a data signal provided by one of the nominal memory cells 140_{N} with a reference signal provided by one of the nominal memory cells 145_{N} that is coupled to one of the data word lines WL_{L}_Ds. Details can be referred to the example illustrated in FIGS. 12-15.

In the operation 1950, the first logic combination of the first to third control signals can correspond to the local reference scheme. When the local reference scheme is applied by the memory controller 140, the memory controller 140 can compare a data signal provided by one of the nominal memory cells 140_{N} with a reference signal provided by another one of the nominal memory cells 140_{N}, in which these two nominal memory cells 140_{N}'s are commonly coupled to one of the data word lines WL_{U}_Ds. Details can be referred to the example illustrated in FIGS. 16-18.

In one aspect of the present disclosure, a semiconductor device is disclosed. The semiconductor device includes a first memory array comprising a plurality of first nominal memory cells, a plurality of first reference memory cells, and a plurality of second reference memory cells; a second array comprising a plurality of second nominal memory cells, a plurality of third reference memory cells, and plurality of fourth reference memory cells; an input/output (I/O) circuit physically interposed between the first memory array and the second memory array along a first lateral direction; and a controller operatively coupled to the I/O circuit, the first memory array, and the second memory array. Based on a plurality of control signals, the controller is configured to select a reference signal from one of the third reference memory cells, the fourth reference memory cells, or the second nominal memory cells, thereby allowing the I/O circuit to sense a data signal from one of the first nominal memory cells.

In another aspect of the present disclosure, a semiconductor device is disclosed. The semiconductor device includes a first memory array comprising a plurality of first memory cells each configured to store a first data bit based on a respective first variable resistance, a plurality of second memory cells each configured to store a first reference resistance, and a plurality of third memory cells each configured to store a second reference resistance; a second array comprising a plurality of fourth memory cells each configured to store a second data bit based on a respective second variable resistance, a plurality of fifth memory cells each configured to store a third reference resistance, and plurality of sixth memory cells each configured to store a fourth reference resistance; and a controller configured to receive a plurality of control signals; and based on a logic combination of the plurality of control signals, (i) select one of the third reference resistance, the fourth reference resistance, or the second data bit to compare with the first data bit, or (ii) select one of the first reference resistance, the second reference resistance, or the first data bit to compare with the second data bit.

In yet another aspect of the present disclosure, a method is disclosed. The method includes receiving at least a first control signal and a second control signal, wherein a logic combination of the first and second control signals is configured to select one of at least a first reference scheme, a second reference scheme, or a third reference scheme. The method includes based on a first one of the logic combination corresponding to the first reference scheme, activating one of a plurality of first reference cells of a first memory array and one of a plurality of second memory cells of a second memory array, thereby comparing a first reference signal provided by the one of the first reference cells with a first data signal provided by the one of the second memory cells. The method includes based on a second one of the logic combination corresponding to the second reference scheme, activating one of a plurality of second reference cells of the first memory array and another of the plurality of second memory cells of the second memory array, thereby comparing a second reference signal provided by the one of the second reference cells with a second data signal provided by the another of second memory cells. The method includes based on a third one of the logic combination corresponding to the third reference scheme, activating one of a plurality of first memory cells of the first memory array and yet another of the plurality of second memory cells of the second memory array, thereby comparing a third data signal provided by the one of the first memory cells with a fourth data signal provided by the yet another of second memory cells.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first memory array comprising a plurality of first nominal memory cells, a plurality of first reference memory cells, and a plurality of second reference memory cells;
a second memory array comprising a plurality of second nominal memory cells, a plurality of third reference memory cells, and plurality of fourth reference memory cells;
an input/output (I/O) circuit physically interposed between the first memory array and the second memory array along a first lateral direction; and
a controller operatively coupled to the I/O circuit, the first memory array, and the second memory array;
wherein, based on a plurality of control signals, the controller is configured to select a reference signal from one of the third reference memory cells, the fourth reference memory cells, or the second nominal memory cells, thereby allowing the I/O circuit to sense a data signal from one of the first nominal memory cells.

2. The semiconductor device of claim 1, further comprising:
a plurality of first drivers operatively coupled between the controller and the first memory array; and
a plurality of second drivers operatively coupled between the controller and the second memory array.

3. The semiconductor device of claim 2, wherein the controller is further configured to:
activate a corresponding one of the second drivers, so as to retrieve the reference signal; and
activate a corresponding one of the first drivers, so as to retrieve the data signal.

4. The semiconductor device of claim 1, wherein the first reference memory cells are alternately arranged with respect to the first nominal memory cells along the first lateral direction, and the third reference memory cells are alternately arranged with respect to the second nominal memory cells along the first lateral direction.

5. The semiconductor device of claim 4, wherein the second reference memory cells are arranged along a first edge of the first memory array extending in a second lateral direction perpendicular to the first lateral direction, and the fourth reference memory cells are arranged along a second edge of the second memory array extending in the second lateral direction.

6. The semiconductor device of claim 5, wherein the I/O circuit is disposed opposite the first edge from the first memory array along the first lateral direction, and the I/O circuit is disposed opposite the second edge from the second memory array along the first lateral direction.

7. The semiconductor device of claim 5, wherein the first edge is disposed opposite the first memory array from the I/O circuit along the first lateral direction, and the second edge is disposed opposite the second memory array from the I/O circuit along the first lateral direction.

8. The semiconductor device of claim 1, wherein the plurality of control signals comprise a first control signal and a second control signal.

9. The semiconductor device of claim 8, wherein, when the first control signal and the second control signal are both provided at a first logic state, the controller is configured to cause the I/O circuit to retrieve the reference signal from the one of the third reference memory cells.

10. The semiconductor device of claim 9, wherein, when the first control signal and the second control signal are provided at a second logic state and the first logic state, respectively, the controller is configured to cause the I/O circuit to retrieve the reference signal from the one of the fourth reference memory cells.

11. The semiconductor device of claim 10, wherein, when the first control signal and the second control signal are provided at the first logic state and the second logic state, respectively, the controller is configured to cause the I/O circuit to retrieve the reference signal from the one of the second reference memory cells.

12. A semiconductor device, comprising:
a first memory array comprising a plurality of first memory cells each configured to store a first data bit based on a respective first variable resistance, a plurality of second memory cells each configured to store a first reference resistance, and a plurality of third memory cells each configured to store a second reference resistance;
a second memory array comprising a plurality of fourth memory cells each configured to store a second data bit based on a respective second variable resistance, a plurality of fifth memory cells each configured to store a third reference resistance, and plurality of sixth memory cells each configured to store a fourth reference resistance; and
a controller configured to:
receive a plurality of control signals; and
based on a logic combination of the plurality of control signals, (i) select one of the third reference resistance, the fourth reference resistance, or the second data bit to compare with the first data bit, or (ii) select one of the first reference resistance, the second reference resistance, or the first data bit to compare with the second data bit.

13. The semiconductor device of claim 12, wherein the first memory array and the second memory array are physically disposed next to each other along a first lateral direction.

14. The semiconductor device of claim 13, wherein:
the plurality of first memory cells are formed as a plurality of first segments extending along a second lateral direction perpendicular to the first lateral direction;
the plurality of second memory cells are formed as a plurality of second segments extending along the second lateral direction;
the plurality of fourth memory cells are formed as a plurality of third segments extending along the second lateral direction;
the plurality of fifth memory cells are formed as a plurality of fourth segments extending along the second lateral direction;
the first segments and the second segments are alternately arranged with respect to each other along the first lateral direction; and
the third segments and the fourth segments are alternately arranged with respect to each other along the first lateral direction.

15. The semiconductor device of claim 14, wherein:
the plurality of third memory cells are formed as one fifth segment extending along the second lateral direction;
the plurality of sixth memory cells are formed as one sixth segment extending along the second lateral direction;
the fifth segment is arranged on one side of a whole of the first segments and the second segments along the first lateral direction; and
the sixth segment is arranged on one side of a whole of the third segments and the fourth segments along the first lateral direction.

16. The semiconductor device of claim 12, wherein, when a first one of the control signals and a second one of the control signals are both provided at a first logic state, the controller is configured to cause a sense amplifier to retrieve the second reference resistance to be compared with the second data bit or the fourth reference resistance to be compared with the first data bit.

17. The semiconductor device of claim 16, wherein, when the first control signal and the second control signal are provided at a second logic state and the first logic state, respectively, the controller is configured to cause the sense amplifier to retrieve the first reference resistance to be compared with the second data bit or the third reference resistance to be compared with the first data bit.

18. The semiconductor device of claim 17, wherein, when the first control signal and the second control signal are provided at the first logic state and the second logic state, respectively, the controller is configured to cause the sense amplifier to retrieve the first data bit to be compared with the second data bit or the second data bit to be compared with the first data bit.

19. A method, comprising:
receiving at least a first control signal and a second control signal, wherein a logic combination of the first and second control signals is configured to select one of at least a first reference scheme, a second reference scheme, or a third reference scheme;
based on a first one of the logic combination corresponding to the first reference scheme, activating one of a plurality of first reference memory cells of a first memory array and one of a plurality of second nominal memory cells of a second memory array, thereby comparing a first reference signal provided by the one of the first reference memory cells with a first data signal provided by the one of the second nominal memory cells;
based on a second one of the logic combination corresponding to the second reference scheme, activating one of a plurality of second reference memory cells of the first memory array and another of the plurality of second nominal memory cells of the second memory array, thereby comparing a second reference signal provided by the one of the second reference memory cells with a second data signal provided by the another of second nominal memory cells; and
based on a third one of the logic combination corresponding to the third reference scheme, activating one of a plurality of first nominal memory cells of the first memory array and yet another of the plurality of second nominal memory cells of the second memory array, thereby comparing a third data signal provided by the one of the first nominal memory cells with a fourth data signal provided by the yet another of the second nominal memory cells.

20. The method of claim 19, wherein:
the first nominal memory cells are alternately arranged with respect to the first reference memory cells along a first lateral direction; and
the second reference memory cells are arranged along an edge of the first memory array extending in a second lateral direction perpendicular to the first lateral direction.
